(19) United States
(12) Patent Application Publication
(10) Pub. No.: US 2020/0168839 A1
(43) Pub. Date: May 28, 2020

(54) OLED PACKAGING METHOD AND OLED PACKAGING STRUCTURE

(71) Applicant: Wuhan China Star Optoelectronics Semiconductor Display Technology Co., LTD, Wuhan, Hubei (CN)

(72) Inventor: Mian ZENG, Wuhan, Hubei (CN)

(21) Appl. No.: 16/087,958

(22) PCT Filed: Sep. 7, 2018
(86) PCT No.: PCT/CN2018/104493

§ 371 Date: Sep. 24, 2018

(30) Foreign Application Priority Data
Feb. 13, 2018 (CN) 201810150416.X

(51) Int. Cl. H01L 51/52; H01L 51/56

(52) U.S. Cl. CPC H01L 51/5253; H01L 51/56

(57) ABSTRACT

The invention provides an OLED packaging method and structure. The method comprises: Step S1: providing a base substrate, forming an OLED element on the base substrate; forming a thin film packaging layer covering the OLED element on the base substrate and the OLED element; Step S2: forming a loop-shaped organic layer surrounding the periphery of the thin film packaging layer on the thin film packaging layer and the base substrate. The use of a loop-shaped organic layer on the periphery of the thin film packaging layer facilitates to achieve a curved screen and narrow border design for OLED display device, as well as improves the water-oxygen blocking capability of the OLED package structure. The OLED package structure of the invention can achieve a curved screen and narrow border design, as well as improve the water-oxygen blocking capability of the OLED package structure.

### BACKGROUND OF THE INVENTION

### 1. Field of the Invention

The present invention relates to the field of display and, in particular, to the field of an OLED manufacturing method and OLED packaging structure.

### 2. The Related Arts

As the organic light-emitting diode (OLED) display provides many advantages such as self-luminescence, low driving voltage, high luminous efficiency, short response time, high definition and high contrast ratio, capability to realize flexible display and large-area full-color display, the OLED display is recognized by the industry as the most promising display device.

The OLED element generally comprises: a substrate, an anode, a hole injection layer, a hole transport layer, a light-emitting layer, an electron transport layer, an electron injection layer, and a cathode. The light-emitting principle behind the OLED element is that the semiconductor material and the organic light-emitting material, driven by the electric field, cause light emission through carrier injection and recombination. Specifically, an OLED element generally employs an indium tin oxide (ITO) electrode and a metal electrode as the anode and the cathode, respectively. When driven by a certain voltage, electrons and holes are injected from the cathode and the anode into the electron transport layer and the hole transport layer, respectively. The electrons and holes migrate to the light-emitting layer through the electron transport layer and the hole transport layer, respectively, and meet at the light-emitting layer to form excitons and excite the light-emitting molecules, which emit visible light through radiation relaxation.

The flexible OLED is an important research direction for OLED elements. The light-emitting material in the OLED element is usually a polymer or organic small molecule. The cathode material is usually made of an active metal with a low work function, such as, magnesium, aluminum, and so on. These light-emitting materials and cathode materials are very sensitive to moisture and oxygen, and the water/oxygen permeation will greatly reduce the lifespan of OLED elements. To achieve the commercialization requirements of the OLED elements in terms of the service life and stability, the requirements on OLED packaging are very high. Therefore, the packaging plays a very important role in the OLED production and is one of the key factors affecting the yield of the products.

The traditional OLED packaging technologies comprise: (1) cover-plate packaging technology: applying UV-curable sealant on the encapsulating glass/metal, or coating the sealant and filling the desiccant, so that the sealant is cured to provide a confined environment for the OLED elements to block water and oxygen from entering; (2) laser packaging technology: glass glue is coated on the packaging glass, and becomes a glass power after the solvent evaporates; after assembling OLED substrate and packaging cover plate, the laser is used to melt the glass powder to achieve adhesion. The above traditional packaging technologies can achieve effective water/oxygen barrier effect, with the side effect of increasing the thickness and weight of the element, which is not conducive to the preparation of flexible OLED.

In recent years, the emerging thin film packaging technology has overcome the drawbacks of traditional packaging technologies. Instead of using packaging covers and sealants to encapsulate OLED elements, the thin film is used to replace the traditional glass packaging to achieve OLED packaging of large dimensions. As such, the OLED elements can be made light and thin. The so-called thin film packaging is to form an inorganic-organic alternating layer on the surface of the OLED element to block water and oxygen by depositing a thin film, wherein the inorganic layer (mainly composed of silicon oxide, silicon nitride, etc.) is an effective water/oxygen blocking layer. However, some pinholes or foreign body defects may be generated during the preparation of the inorganic layer, and the organic layer (mainly composed of high molecular polymer, resin, etc.) functions to cover the defects of the inorganic layer, to achieve planarization, and to release the stress between the inorganic layers to achieve flexible packaging.

FIG. 1 is a schematic cross-sectional view of a conventional OLED thin film packaging structure. The OLED thin film packaging structure comprises a base substrate 100, an OLED element 200 disposed on the base substrate 100, and a thin film packaging layer 300 covering the base substrate 100 and the OLED element 200;

in a direction parallel to the base substrate 100, the thin film packaging layer 300 comprising a central region 310 corresponding to the OLED element 200 and an edge region 320 corresponding to surroundings of the OLED element 200;

in a direction perpendicular to the base substrate 100, the thin film packaging layer 300 comprising an inorganic blocking layer 500 and an organic buffer layer 600 alternately stacked on the OLED element 200 and the base substrate 100; wherein the inorganic blocking layer 500 having an area greater than area of the underneath organic buffer layer 600 so that the inorganic blocking layers 500 being stacked together to form an inorganic layer stacking region 3210 on outside of the edge region 320 of the thin film packaging layer 300.

To ensure that the water and oxygen do not permeate into the OLED element 200 from the edge of the base substrate 100 and result in abnormal display, the edge region 320 of the thin film packaging layer 300 generally needs to reserve a larger width because when the OLED packaging structure is used to fabricate an OLED display device, the edge region 320 of the thin film packaging layer 300 needs to be shielded with a frame. Therefore, a larger width of the edge region 320 is not conducive to the realization of a narrow border design. In addition, since the flexibility of the inorganic layer stacking region 3210 of the edge region 320 of the thin film packaging layer 300 is smaller, when the edge region 320 of the thin film packaging layer 300 is bent, the inorganic blocking layer 500 in the inorganic layer stacking region 3210 is easily broken due to excessive stress to cause water and oxygen to permeate into, which is unfavorable for realizing the current popular curved screen (panel edge bending) design.

### SUMMARY OF THE INVENTION

The primary object of the present invention is to provide an OLED packaging method, conductive to realize the curved screen and narrow border design, as well as able to improve the water/oxygen blocking capability of the OLED structure.

Another object of the present invention is to provide an OLED packaging structure, able to realize the curved screen and narrow border design, as well as stronger the water/oxygen blocking capability.

To achieve the above objects, the present invention provides an OLED packaging method, which comprises:

Step S1: providing a base substrate, forming an OLED element on the base substrate; forming a thin film packaging layer covering the OLED element on the base substrate and the OLED element;

in a direction parallel to the base substrate, the thin film packaging layer comprising a central region above and corresponding to the OLED element and an edge region corresponding to the periphery of the OLED element:

in a direction perpendicular to the base substrate, the thin film packaging layer comprising an inorganic blocking layer and an organic buffer layer alternately stacked on the OLED element and the base substrate, wherein the inorganic blocking layer having an area greater than area of the underneath organic buffer layer so that the inorganic blocking layers being stacked together to form an inorganic layer stacking region outside of the edge region of the thin film packaging layer;

Step S2: forming a loop-shaped organic layer surrounding the periphery of the thin film packaging layer on the thin film packaging layer and the base substrate; an outer edge of the loop-shaped organic layer being on the base substrate, and the loop-shaped organic layer at least covering the inorganic layer stacking region outside the edge region of the thin film packaging layer; curing the loop-shaped organic layer to obtain an OLED packaging structure.

According to a preferred embodiment of the present invention, the loop-shaped organic layer covers entire area of the edge region of the thin film packaging layer.

According to a preferred embodiment of the present invention, the inorganic blocking layer is made of one or more of silicon oxide and silicon nitride; the inorganic blocking layer is prepared by a chemical vapor deposition method; the organic buffer layer is made of an organic resin, and the organic buffer layer is prepared by an inkjet printing method.

According to a preferred embodiment of the present invention, the thin film packaging layer comprises an inorganic blocking layer, an organic buffer layer, and an inorganic blocking layer stacked in sequence from the bottom to the top of the OLED element and the base substrate.

According to a preferred embodiment of the present invention, the loop-shaped organic layer is made of one or more of a UV curable adhesive and a thermo-curable adhesive with water-blocking oxygen-blocking properties.

The present invention also provides an OLED structure, which comprises a base substrate, an OLED element formed on the base substrate; a thin film packaging layer covering the OLED element formed on the base substrate and the OLED element; a loop-shaped organic layer surrounding the periphery of the thin film packaging layer formed on the thin film packaging layer and the base substrate;

in a direction parallel to the base substrate, the thin film packaging layer comprising a central region above and corresponding to the OLED element and an edge region corresponding to the periphery of the OLED element;

in a direction perpendicular to the base substrate, the thin film packaging layer comprising an inorganic blocking layer and an organic buffer layer alternately stacked on the OLED element and the base substrate, wherein the inorganic blocking layer having an area greater than area of the underneath organic buffer layer so that the inorganic blocking layers being stacked together to form an inorganic layer stacking region outside of the edge region of the thin film packaging layer;

an outer edge of the loop-shaped organic layer being on the base substrate, and the loop-shaped organic layer at least covering the inorganic layer stacking region outside the edge region of the thin film packaging layer.

According to a preferred embodiment of the present invention, the loop-shaped organic layer covers entire area of the edge region of the thin film packaging layer.

According to a preferred embodiment of the present invention, the loop-shaped organic layer is made of one or more of a UV curable adhesive and a thermo-curable adhesive with water-blocking oxygen-blocking properties.

According to a preferred embodiment of the present invention, the inorganic blocking layer is made of one or more of silicon oxide and silicon nitride; the organic buffer layer is made of an organic resin.

According to a preferred embodiment of the present invention, the thin film packaging layer comprises an inorganic blocking layer, an organic buffer layer, and an inorganic blocking layer stacked in sequence from the bottom to the top of the OLED element and the base substrate.

The present invention also provides an OLED packaging method, which comprises:

Step S1: providing a base substrate, forming an OLED element on the base substrate; forming a thin film packaging layer covering the OLED element on the base substrate and the OLED element;

in a direction parallel to the base substrate, the thin film packaging layer comprising a central region above and corresponding to the OLED element and an edge region corresponding to the periphery of the OLED element;

in a direction perpendicular to the base substrate, the thin film packaging layer comprising an inorganic blocking layer and an organic buffer layer alternately stacked on the OLED element and the base substrate, wherein the inorganic blocking layer having an area greater than area of the underneath organic buffer layer so that the inorganic blocking layers being stacked together to form an inorganic layer stacking region outside of the edge region of the thin film packaging layer;

Step S2: forming a loop-shaped organic layer surrounding the periphery of the thin film packaging layer on the thin film packaging layer and the base substrate; an outer edge of the loop-shaped organic layer being on the base substrate, and the loop-shaped organic layer at least covering the inorganic layer stacking region outside the edge region of the thin film packaging layer; curing the loop-shaped organic layer to obtain an OLED packaging structure;

wherein the loop-shaped organic layer covering entire area of the edge region of the thin film packaging layer;

wherein the inorganic blocking layer being made of one or more of silicon oxide and silicon nitride; the inorganic blocking layer being prepared by a chemical vapor deposition method; the organic buffer layer being made of an organic resin, and the organic buffer layer being prepared by an inkjet printing method;

wherein the thin film packaging layer comprising an inorganic blocking layer, an organic buffer layer, and an inorganic blocking layer stacked in sequence from the bottom to the top of the OLED element and the base substrate;

wherein the loop-shaped organic layer being made of one or more of a UV curable adhesive and a thermo-curable adhesive with water-blocking oxygen-blocking properties.

The present invention provides the following advantages: the OLED packaging method of the present invention, by providing a loop-shaped organic layer on the periphery of the thin film packaging layer, uses the loop-shaped organic layer to closely adhere the thin film packaging layer and the base substrate together to protect the edge of the thin film packaging layer. When the edge region of the thin film packaging layer is bent to achieve a curved screen design, the loop-shaped organic layer can release and buffer the stress on the inorganic layer stack region outside the edge region, preventing the inorganic blocking layer in the inorganic layer stack region from breakage due to excessive stress to cause water and oxygen to permeate, thereby improving the water-oxygen blocking capability of the OLED package structure. In the meantime, the present invention is also beneficial to realize the narrow border design of the OLED display device. The OLED package structure of the present invention, by providing a loop-shaped organic layer at the periphery of the thin-film packaging layer, makes the edge region of the thin film packaging layer more flexible, as well as improving the packaging effect of the OLED packaging structure while beneficial to realize the narrow border design of the OLED display device.

### BRIEF DESCRIPTION OF THE DRAWINGS

To make the technical solution of the embodiments according to the present invention, a brief description of the drawings that are necessary for the illustration of the embodiments will be given as follows. Apparently, the drawings described below show only example embodiments of the present invention and for those having ordinary skills in the art, other drawings may be easily obtained from these drawings without paying any creative effort.

FIG. 1 is a schematic cross-sectional view showing the traditional OLED thin film packaging structure.

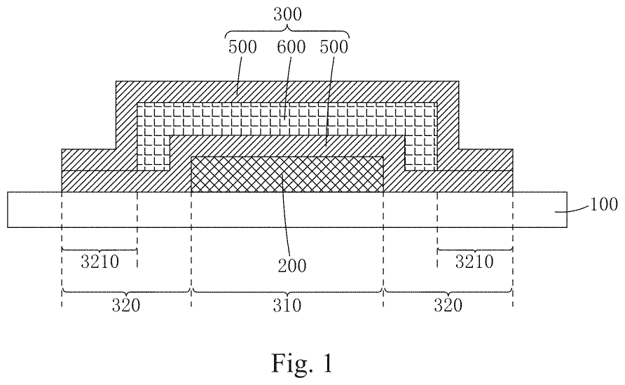

FIG. 2 is a schematic view showing the flowchart of the OLED packaging method according to an exemplary embodiment of the present invention.

FIG. 3 is a schematic cross-sectional view showing step S1 of the OLED packaging method according to an exemplary embodiment of the present invention.

FIG. 4 is a schematic top view showing step S1 of the OLED packaging method according to an exemplary embodiment of the present invention.

FIG. 5 is a schematic cross-sectional view showing step S2 of the OLED packaging method and the OLED packaging structure according to an exemplary embodiment of the present invention.

FIG. 6 is a schematic top view showing step S2 of the OLED packaging method and the OLED packaging structure according to an exemplary embodiment of the present invention.

### DETAILED DESCRIPTION OF THE PREFERRED EMBODIMENTS

To further explain the technical means and effect of the present invention, the following refers to embodiments and drawings for detailed description. Apparently, the described embodiments are merely some embodiments of the present invention, instead of all embodiments. All other embodiments based on embodiments in the present invention and obtained by those skilled in the art without departing from the creative work of the present invention are within the scope of the present invention.

The terms “comprising” and “having” and any variations thereof appearing in the specification, claims, and drawings of the present application are intended to cover non-exclusive inclusion. For example, a process, method, system, product, or device that includes a series of steps or units is not limited to the listed steps or units, but optionally also includes steps or units not listed, or alternatively, other steps or units inherent to these processes, methods, products or equipment. In addition, the terms “first”, “second” and “third” are used to distinguish different objects and not intended to describe a particular order.

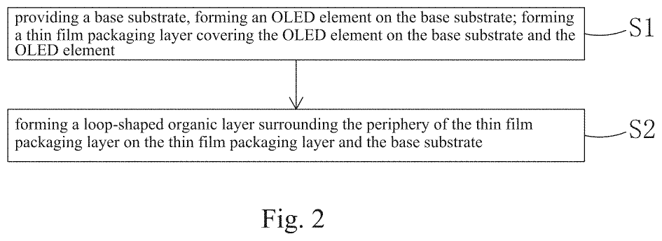

As shown in FIG. 2, the present invention provides an OLED packaging method, which comprises:

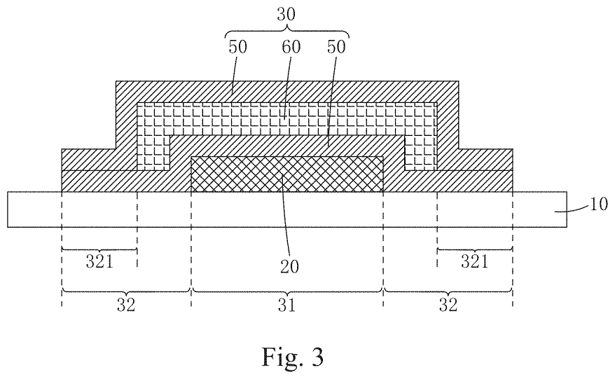

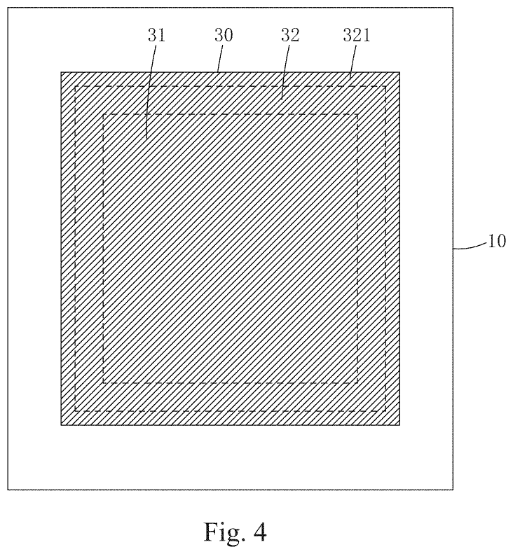

Step S1: as shown in FIG. 3 and FIG. 4, providing a base substrate 10, forming an OLED element 20 on the base substrate 10; forming a thin film packaging layer 30 covering the OLED element 20 on the base substrate 10 and the OLED element 20;

in a direction parallel to the base substrate 10, the thin film packaging layer 30 comprising a central region 31 above and corresponding to the OLED element 20 and an edge region 32 corresponding to the periphery of the OLED element 20;

in a direction perpendicular to the base substrate 10, the thin film packaging layer 30 comprising an inorganic blocking layer 50 and an organic buffer layer 60 alternately stacked on the OLED element 20 and the base substrate 10, wherein the inorganic blocking layer 50 having an area greater than area of the underneath organic buffer layer 60 so that the inorganic blocking layers 50 being stacked together to form an inorganic layer stacking region 321 outside of the edge region 32 of the thin film packaging layer 30.

Specifically, the inorganic blocking layer 50 is made of one or more of silicon oxide and silicon nitride; and the inorganic blocking layer 50 is prepared by a chemical vapor deposition (CVD) method.

The organic buffer layer 60 is made of an organic resin, and the organic buffer layer 60 is prepared by an inkjet printing (IJP) method.

Preferably, the thin film packaging layer 30 comprises an inorganic blocking layer 50, an organic buffer layer 60, and an inorganic blocking layer 50 stacked in sequence from the bottom to the top of the OLED element 20 and the base substrate 10.

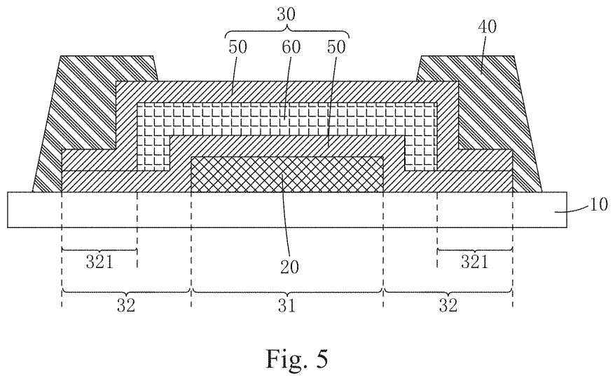

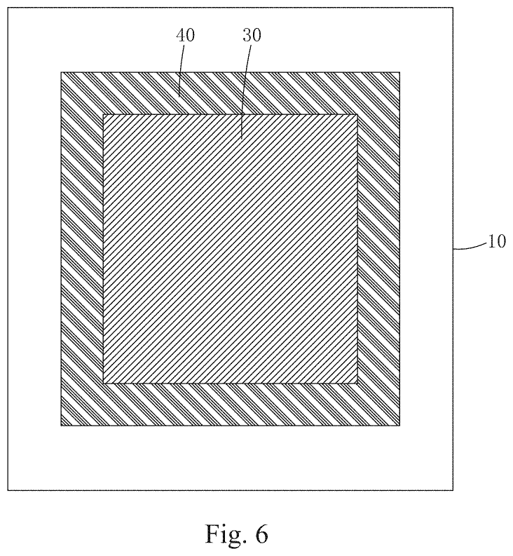

Step S2: as shown in FIG. 5 and FIG. 6, forming a loop-shaped organic layer 40 surrounding the periphery of the thin film packaging layer 30 on the thin film packaging layer 30 and the base substrate 10; an outer edge of the loop-shaped organic layer 40 being on the base substrate 10, and the loop-shaped organic layer 30 at least covering the inorganic layer stacking region 321 outside the edge region 32 of the thin film packaging layer 30; curing the loop-shaped organic layer 40 to obtain an OLED packaging structure.

Specifically, in step S2, a coating method is used to form a ring-shaped organic layer 40 surrounding the periphery of the thin film packaging layer 30 on the thin film packaging layer 30 and the base substrate 10.

Optionally, to enhance the adhesion between the thin film packaging layer 30 and the base substrate 10 as well as the water-blocking property of the OLED package structure, the loop-shaped organic layer 40 covers entire area of the edge region 32 of the thin film packaging layer 30.

Specifically, the loop-shaped organic layer 40 is made of one or more of a UV curable adhesive, a thermo-curable adhesive or other curable adhesive with water-blocking oxygen-blocking properties.

When the OLED package structure manufactured by the present invention is used to fabricate an OLED display device, the edge region 32 of the thin film packaging layer 30 usually needs to be shielded with a frame. In other words, the width of the edge area 32 is proportional to the width of frame of the OLED display device. Therefore, reducing the width of the edge area 32 is advantageous to realize the narrow border design of the OLED display device.

Specifically, the present invention uses the loop-shaped organic layer 40 to closely adhere the thin film packaging layer 30 and the base substrate 10 together to protect the edge region 32 of the thin film packaging layer 30. When the edge region 32 of the thin film packaging layer 30 is bent to achieve a curved screen design, the loop-shaped organic layer 40 can release and buffer the stress on the inorganic layer stack region 321 outside the edge region 32, preventing the inorganic blocking layer 50 in the inorganic layer stack region 321 from breakage due to excessive stress to cause water and oxygen to permeate, thereby improving the water-oxygen blocking capability of the OLED package structure. In the case wherein the packaging effect of the OLED package structure is improved, the width of the edge region 32 of the thin film packaging layer 30 can be appropriately reduced, thereby facilitating the realization of the narrow border design of the OLED display device.

Refer to FIG. 5 and FIG. 6. Based on the above OLED manufacturing method, the present invention provides an OLED structure, which comprises a base substrate 10, an OLED element 20 formed on the base substrate 10; a thin film packaging layer 30 covering the OLED element 20 formed on the base substrate 10 and the OLED element 20; a loop-shaped organic layer 40 surrounding the periphery of the thin film packaging layer 30 formed on the thin film packaging layer 30 and the base substrate 10;

in a direction parallel to the base substrate 10, the thin film packaging layer 30 comprising a central region 31 above and corresponding to the OLED element 20 and an edge region 32 corresponding to the periphery of the OLED element 20;

in a direction perpendicular to the base substrate 10, the thin film packaging layer 30 comprising an inorganic blocking layer 50 and an organic buffer layer 60 alternately stacked on the OLED element 20 and the base substrate 10, wherein the inorganic blocking layer 50 having an area greater than area of the underneath organic buffer layer 60 so that the inorganic blocking layers 50 being stacked together to form an inorganic layer stacking region 321 outside of the edge region 32 of the thin film packaging layer 30;

an outer edge of the loop-shaped organic layer 40 being on the base substrate 10, and the loop-shaped organic layer 40 at least covering the inorganic layer stacking region 321 outside the edge region 32 of the thin film packaging layer 30.

Optionally, to enhance the adhesion between the thin film packaging layer 30 and the base substrate 10 as well as the water-blocking property of the OLED package structure, the loop-shaped organic layer 40 covers entire area of the edge region 32 of the thin film packaging layer 30.

Specifically, the loop-shaped organic layer 40 is made of one or more of a UV curable adhesive, a thermo-curable adhesive or other curable adhesive with water-blocking oxygen-blocking properties.

Specifically, the inorganic blocking layer 50 is made of one or more of silicon oxide and silicon nitride; the organic buffer layer 60 is made of an organic resin.

Preferably, the thin film packaging layer 30 comprises an inorganic blocking layer 50, an organic buffer layer 60, and an inorganic blocking layer 50 stacked in sequence from the bottom to the top of the OLED element 20 and the base substrate 10.

In summary, the OLED packaging method of the present invention, by providing a loop-shaped organic layer on the periphery of the thin film packaging layer, uses the loop-shaped organic layer to closely adhere the thin film packaging layer and the base substrate together to protect the edge of the thin film packaging layer. When the edge region of the thin film packaging layer is bent to achieve a curved screen design, the loop-shaped organic layer can release and buffer the stress on the inorganic layer stack region outside the edge region, preventing the inorganic blocking layer in the inorganic layer stack region from breakage due to excessive stress to cause water and oxygen to permeate, thereby improving the water-oxygen blocking capability of the OLED package structure. In the meantime, the present invention is also beneficial to realize the narrow border design of the OLED display device. The OLED package structure of the present invention, by providing a loop-shaped organic layer at the periphery of the thin-film packaging layer, makes the edge region of the thin film packaging layer more flexible, as well as improving the packaging effect of the OLED packaging structure while beneficial to realize the narrow border design of the OLED display device.

It should be noted that each of the embodiments in this specification is described in a progressive manner, each of which is primarily described in connection with other embodiments with emphasis on the difference parts, and the same or similar parts may be seen from each other. For the device embodiment, since it is substantially similar to the method embodiment, the description is relatively simple and the relevant description may be described in part of the method embodiment.

Embodiments of the present invention have been described, but not intending to impose any unduly constraint to the appended claims. Any modification of equivalent structure or equivalent process made according to the disclosure and drawings of the present invention, or any application thereof, directly or indirectly, to other related fields of technique, is considered encompassed in the scope of protection defined by the claims of the present invention.

What is claimed is:

1. An organic light-emitting diode (OLED) packaging method, comprising:
Step S1: providing a base substrate, forming an OLED element on the base substrate; forming a thin film packaging layer covering the OLED element on the base substrate and the OLED element;
in a direction parallel to the base substrate, the thin film packaging layer comprising a central region above and corresponding to the OLED element and an edge region corresponding to the periphery of the OLED element;
in a direction perpendicular to the base substrate, the thin film packaging layer comprising an inorganic blocking layer and an organic buffer layer alternately stacked on the OLED element and the base substrate, wherein the inorganic blocking layer having an area greater than area of the underneath organic buffer layer so that the inorganic blocking layers being stacked together to form an inorganic layer stacking region outside of the edge region of the thin film packaging layer;
Step S2: forming a loop-shaped organic layer surrounding the periphery of the thin film packaging layer on the thin film packaging layer and the base substrate; an outer edge of the loop-shaped organic layer being on the base substrate, and the loop-shaped organic layer at least covering the inorganic layer stacking region outside the edge region of the thin film packaging layer; curing the loop-shaped organic layer to obtain an OLED packaging structure.

2. The OLED packaging method as claimed in claim 1, wherein the loop-shaped organic layer covers entire area of the edge region of the thin film packaging layer.

3. The OLED packaging method as claimed in claim 1, wherein the inorganic blocking layer is made of one or more of silicon oxide and silicon nitride; the inorganic blocking layer is prepared by a chemical vapor deposition method; the organic buffer layer is made of an organic resin, and the organic buffer layer is prepared by an inkjet printing method.

4. The OLED packaging method as claimed in claim 1, wherein the thin film packaging layer comprises an inorganic blocking layer, an organic buffer layer, and an inorganic blocking layer stacked in sequence from the bottom to the top of the OLED element and the base substrate.

5. The OLED packaging method as claimed in claim 1, wherein the loop-shaped organic layer is made of one or more of a UV curable adhesive and a thermo-curable adhesive with water-blocking oxygen-blocking properties.

6. An organic light-emitting diode (OLED) packaging structure, comprising: a base substrate, an OLED element formed on the base substrate; a thin film packaging layer covering the OLED element formed on the base substrate and the OLED element; a loop-shaped organic layer surrounding the periphery of the thin film packaging layer formed on the thin film packaging layer and the base substrate;
in a direction parallel to the base substrate, the thin film packaging layer comprising a central region above and corresponding to the OLED element and an edge region corresponding to the periphery of the OLED element;
in a direction perpendicular to the base substrate, the thin film packaging layer comprising an inorganic blocking layer and an organic buffer layer alternately stacked on the OLED element and the base substrate, wherein the inorganic blocking layer having an area greater than area of the underneath organic buffer layer so that the inorganic blocking layers being stacked together to form an inorganic layer stacking region outside of the edge region of the thin film packaging layer;
an outer edge of the loop-shaped organic layer being on the base substrate, and the loop-shaped organic layer at least covering the inorganic layer stacking region outside the edge region of the thin film packaging layer.

7. The OLED packaging structure as claimed in claim 6, wherein the loop-shaped organic layer covers entire area of the edge region of the thin film packaging layer.

8. The OLED packaging structure as claimed in claim 6, wherein the loop-shaped organic layer is made of one or more of a UV curable adhesive and a thermo-curable adhesive with water-blocking oxygen-blocking properties.

9. The OLED packaging structure as claimed in claim 6, wherein the inorganic blocking layer is made of one or more of silicon oxide and silicon nitride; the organic buffer layer is made of an organic resin.

10. The OLED packaging structure as claimed in claim 6, wherein the thin film packaging layer comprises an inorganic blocking layer, an organic buffer layer, and an inorganic blocking layer stacked in sequence from the bottom to the top of the OLED element and the base substrate.

11. An organic light-emitting diode (OLED) packaging method, comprising:
Step S1: providing a base substrate, forming an OLED element on the base substrate; forming a thin film packaging layer covering the OLED element on the base substrate and the OLED element;
in a direction parallel to the base substrate, the thin film packaging layer comprising a central region above and corresponding to the OLED element and an edge region corresponding to the periphery of the OLED element;
in a direction perpendicular to the base substrate, the thin film packaging layer comprising an inorganic blocking layer and an organic buffer layer alternately stacked on the OLED element and the base substrate, wherein the inorganic blocking layer having an area greater than area of the underneath organic buffer layer so that the inorganic blocking layers being stacked together to form an inorganic layer stacking region outside of the edge region of the thin film packaging layer;
Step S2: forming a loop-shaped organic layer surrounding the periphery of the thin film packaging layer on the thin film packaging layer and the base substrate; an outer edge of the loop-shaped organic layer being on the base substrate, and the loop-shaped organic layer at least covering the inorganic layer stacking region outside the edge region of the thin film packaging layer; curing the loop-shaped organic layer to obtain an OLED packaging structure;
wherein the loop-shaped organic layer covering entire area of the edge region of the thin film packaging layer;
wherein the inorganic blocking layer being made of one or more of silicon oxide and silicon nitride; the inorganic blocking layer being prepared by a chemical vapor deposition method; the organic buffer layer being made of an organic resin, and the organic buffer layer being prepared by an inkjet printing method;
wherein the thin film packaging layer comprising an inorganic blocking layer, an organic buffer layer, and an inorganic blocking layer stacked in sequence from the bottom to the top of the OLED element and the base substrate;
wherein the loop-shaped organic layer being made of one or more of a UV curable adhesive and a thermo-curable adhesive with water-blocking oxygen-blocking properties.
